(19) United States
(12) Patent Application Publication
(10) Pub. No.: US 2011/0209752 A1
(43) Pub. Date: Sep. 1, 2011

(54) MICROSTRUCTURED GLASS SUBSTRATES

(76) Inventors: Glenn Eric Kohnke, Corning, NY (US); Jia Liu, Painted Post, NY (US)

(21) Appl. No.: 13/033,075

(22) Filed: Feb. 23, 2011

Related U.S. Application Data
(60) Provisional application No. 61/308,611, filed on Feb. 26, 2010.

(51) Int. Cl. H01L 31/0216; B05D 5/12; B32B 3/00

(52) U.S. Cl. 136/256; 427/74; 428/206

(57) ABSTRACT

Light scattering inorganic substrates comprising monolayers and methods for making light scattering inorganic substrates comprising monolayers useful for, for example, photovoltaic cells are described herein. One embodiment is a method for making a light scattering inorganic substrate. The method comprises providing an inorganic substrate comprising at least one surface, forming a monolayer of inorganic particles on the at least one surface to form a coated substrate, heating the coated substrate above the softening point of the inorganic substrate, and pressing the inorganic particles into the at least one surface form the light scattering inorganic substrate.

This application claims the benefit of priority to U.S. Provisional Patent Application No. 61/308,611 filed Feb. 26, 2010.

### BACKGROUND

1. Field

Embodiments relate generally to articles such as light scattering inorganic substrates and methods for making light scattering inorganic substrates, and more particularly to light scattering inorganic substrates comprising monolayers and methods for making light scattering inorganic substrates comprising monolayers useful for, for example, photovoltaic cells.

2. Technical Background

For thin-film silicon photovoltaic solar cells, light must be effectively coupled into the silicon layer and subsequently trapped in the layer to provide sufficient path length for light absorption. A path length greater than the thickness of the silicon is especially advantageous at longer wavelengths where the silicon absorption length is typically tens to hundreds of microns. Light is typically incident from the side of the deposition substrate such that the substrate becomes a superstrate in the cell configuration. A typical tandem cell incorporating both amorphous and microcrystalline silicon typically has a substrate having a transparent electrode deposited thereon, a top cell of amorphous silicon, a bottom cell of microcrystalline silicon, and a back contact or counter electrode.

Amorphous silicon absorbs primarily in the visible portion of the spectrum below 700 nanometers (nm) while microcrystalline silicon absorbs similarly to bulk crystalline silicon with a gradual reduction in absorption extending to ˜1200 nm. Both types of material benefit from textured surfaces. Depending on the size scale of the texture, the texture performs light trapping and/or reduces Fresnel loss at the Si/substrate interface.

The transparent electrode (also known as transparent conductive oxide, TCO) is typically a film of fluorine doped-SnO₂ or boron or aluminum doped-ZnO with a thickness on the order of 1 micron that is textured to scatter light into the amorphous Si and the microcrystalline Si. The primary measure of scattering is called “haze” and is defined as the ratio of light that is scattered >2.5 degrees out of a beam of light going into a sample and the total light transmitted through the sample. The scattering distribution function is not captured by this single parameter and large angle scattering is more beneficial for enhanced path length in the silicon compared with narrow angle scattering. Additional work on different types of scattering functions indicate that improved large angle scattering has a significant impact on cell performance.

Typically, the TCO surface is textured by various techniques. For SnO₂ or ZnO films deposited by chemical vapor deposition (CVD), the texture is primarily controlled by deposition conditions and film thickness. For sputtered films, the texture can be modified by etching such as wet etching. Plasma etching has also been used with CVD ZnO to control texture.

Disadvantages with textured TCO technology can include one or more of the following: 1) texture roughness degrades the quality of the deposited silicon and creates electrical shorts such that the overall performance of the solar cell is degraded; 2) texture optimization is limited both by the textures available from the deposition or etching process and the decrease in transmission associated with a thicker TCO layer; and 3) plasma treatment or wet etching to create texture adds cost in the case of ZnO.

Another approach to the light-trapping needs for thin film silicon solar cells is texturing of the substrate beneath the TCO and/or the silicon prior to silicon deposition, rather than texture a deposited film. In some conventional thin film silicon solar cells, vias are used instead of a TCO to make contacts at the bottom of the Si that is in contact with the substrate. The texturing in some conventional thin film silicon solar cells consist of SiO₂ particles in a binder matrix deposited on a planar glass substrate. This type of texturing is typically done using a sol-gel type process where the particles are suspended in liquid; the substrate is drawn through the liquid, and subsequently sintered. The beads remain spherical in shape and are held in place by the sintered gel.

Many additional methods have been explored for creating a textured surface prior to TCO deposition. These methods include sandblasting, polystyrene microsphere deposition and etching, and chemical etching. These methods related to textured surfaces can be limited in terms of the types of surface textures that can be created.

Light trapping is also beneficial for bulk crystalline Si solar cells having a Si thickness less than about 100 microns. At this thickness, there is insufficient thickness to effectively absorb all the solar radiation in a single or double pass (with a reflecting back contact). Therefore, cover glasses with large scale geometric structures have been developed to enhance the light trapping. For example, an EVA (ethyl-vinyl acetate) encapsulant material is located between the cover glass and the silicon. An example of such cover glasses are the Albarino® family of products from Saint-Gobain Glass. A rolling process is typically used to form this large-scale structure.

Disadvantages with the textured glass superstrate approach can include one or more of the following: 1) sol-gel chemistry and associated processing is required to provide binding of glass microspheres to the substrate; 2) the process creates textured surfaces on both sides of the glass substrate; 3) additional costs associated with silica microspheres and sol-gel materials; and 4) problems of film adhesion and/or creation of cracks in the silicon film.

Micro-textured glass has been explored for other applications including hydrophobic coatings. A method of depositing high temperature nanoparticles or microparticles onto a hot glass substrate was developed by Ferro Corporation. In this technique, particles are sprayed onto a substrate while it is on a hot float bath. The technique does not offer control over particle depth, the uniformity of the surface coverage is unknown, and it is unclear if monolayer deposition is possible. Coatings formed by nanoparticle deposition on hot glass substrates were also investigated by both PPG and Beneqoy. These coatings are typically made with particles less than 1000 nm and do not consist of a single layer.

US20070116913 discusses particle deposition or direct imprinting on glass coming off an isopipe in a fusion process. Particle deposition may occur above the fusion pipe, along the side of the fusion pipe, or below the fusion pipe. It does not describe pressing particles into the glass. It describes generally the use of any type of glass particles. It specifically describes the use of glass particles that are the same composition as the fusion glass. It also describes the use of high temperature particles which are subsequently removed to form features.

It would be advantageous to have an article such as a light scattering inorganic substrate and a method for making a light scattering inorganic substrate wherein a monolayer of particles could be formed on the substrate.

### SUMMARY

Articles such as light scattering inorganic substrates and/or methods for making a light scattering inorganic substrate, as described herein, address one or more of the above-mentioned disadvantages of conventional methods and may provide one or more of the following advantages: the glass microstructure coated with TCO may be smoothly varying and less likely to create electrical problems, the glass texture may be optimized without concern of an absorption penalty unlike in the case of a textured TCO more texture requires regions of thicker TCO resulting in higher absorption, the process does not require a binder that can be sintered as in the case of sol-gel processes, and the texture feature size may be controlled with the particle size distribution.

One embodiment is a method for making a light scattering inorganic substrate. The method comprises providing an inorganic substrate comprising at least one surface, forming a monolayer of inorganic particles on the at least one surface to form a coated substrate, and heating the coated substrate above the softening point of the inorganic substrate to form the light scattering inorganic substrate.

Another embodiment is an article comprising an inorganic substrate having two opposing surfaces; and inorganic particles disposed on at least one of the opposing surfaces, wherein a majority of the particles have a portion of their volume above the surface they are disposed on and wherein the portion is less than ¾ of the volume of the particle. In one embodiment, the portion is less than ⅔ of the volume of the particle, for example, less than ½, for example, less than ⅓.

Another embodiment is an article comprising an inorganic substrate having two opposing surfaces; and inorganic particles disposed on at least one of the opposing surfaces, wherein the majority of the particles have average diameters in the range of from 0.1 to 20 microns, and wherein the majority of the particles have a center-to-center spacing less than twice the average particle diameter.

An article comprising an inorganic substrate having two opposing surfaces; and voids on at least one of the opposing surfaces, the surface has voids, wherein the height of the voids are 0.1 to 20 microns.

In one embodiment, the described articles comprise the inorganic particles disposed in a monolayer. The articles can be light scattering inorganic substrates and can be used in thin film photovoltaic solar cells.

Embodiments herein describe light scattering glass substrates formed by depositing a monolayer of glass microspheres or glass microparticles followed by heating and optionally pressing the particles into the inorganic substrate. The light scattering inorganic substrates can be used in thin film photovoltaic solar cells.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIGS. 1A, 1B, and 1C are top down scanning electron microscope (SEM) images of light scattering inorganic substrates made according to one embodiment.

FIGS. 1D, 1E, and 1F are cross sectional SEM images of the light scattering inorganic substrates shown in FIGS. 1A, 1B, and 1C, respectively.

FIGS. 2A, 2B, and 2C are 1-D line scans of ccBTDF (cosine-corrected bidirectional transmittance distribution function) measurements which correspond to the light scattering inorganic substrates shown FIGS. 1A, 1B, and 1C, respectively.

FIG. 3 is a plot of total and diffuse transmittance which corresponds to the light scattering inorganic substrates shown FIGS. 1A, 1B, and 1C, respectively.

FIG. 4 is a cross-sectional illustration of an article, according to one embodiment.

FIG. 5 is a cross-sectional SEM image of an article, according to one embodiment.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

Although exemplary numerical ranges are described in the embodiments, each of the ranges can include any numerical value including decimal places within the range included in each of the ranges.

One embodiment is a method for making a light scattering inorganic substrate. The method comprises providing an inorganic substrate comprising at least one surface, forming a monolayer of inorganic particles on the at least one surface to form a coated substrate, and heating the coated substrate above the softening point of the inorganic substrate to form the light scattering inorganic substrate.

Another embodiment is a method for making a light scattering inorganic substrate. The method comprises providing an inorganic substrate comprising at least one surface, forming a monolayer of inorganic particles on the at least one surface to form a coated substrate, heating the coated substrate above the softening point of the inorganic substrate, and pressing the inorganic particles into the at least one surface to form the light scattering inorganic substrate.

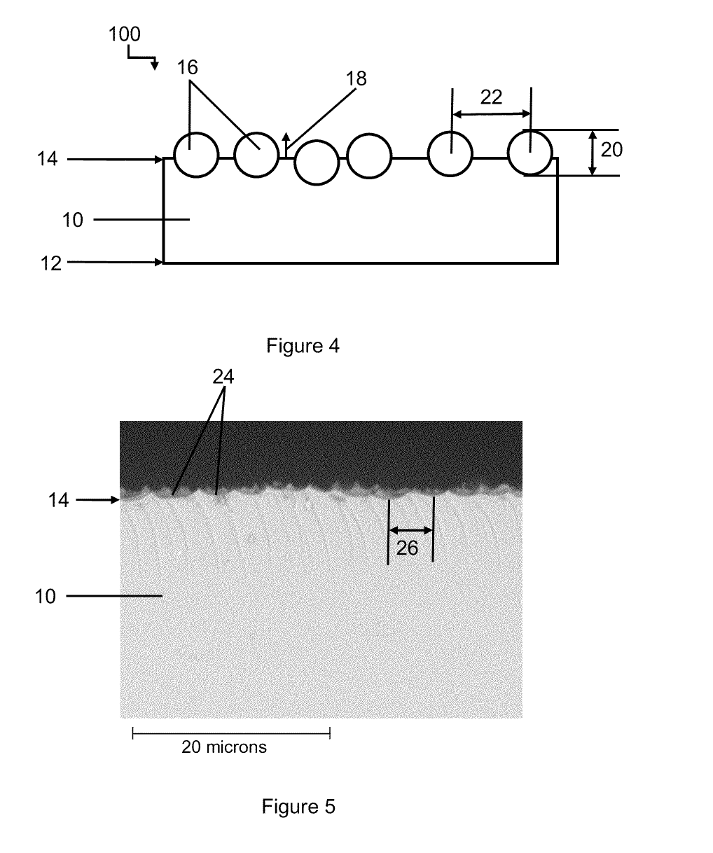

Another embodiment, as shown in FIG. 4, is an article 100 comprising an inorganic substrate 10 having two opposing surfaces 12 and 14; and inorganic particles 16 disposed on at least one of the opposing surfaces, for example, surface 14 wherein a majority of the particles have a portion of their volume above the surface, as shown by arrow 18, they are disposed on and wherein the portion is less than ¾ of the volume of the particle.

Another embodiment, as shown in FIG. 4, is an article 100 comprising an inorganic substrate 10 having two opposing surfaces 12 and 14; and inorganic particles 16 disposed on at least one of the opposing surfaces, for example, surface 14 wherein the majority of the particles have average diameters, shown by arrow 20, in the range of from 0.1 to 20 microns, and wherein the majority of the particles have a center-to-center spacing, shown by arrow 22, less than twice the average particle diameter.

The articles can be light scattering inorganic substrates and can be used in photovoltaic devices such as thin film photovoltaic solar cells.

In one embodiment, the light scattering inorganic substrate is formed by pressing a monolayer of high temperature particles into a lower temperature substrate with a controlled depth. The particles may be delivered to the low temperature substrate by forming a monolayer on the substrate, forming the monolayer on a carrier used for pressing, or spraying/sprinkling an excess of particles on the substrate and removing all or the excess after pressing. If concave surface features are more preferable than convex surface features, the high temperature particles may be etched off the surface. The particles are of a controlled size and may be of a single size or a distribution of sizes.

The size of the particles is, according to one embodiment, 20 μm or less, for example, 0.1 μm to 20 μm, for example, 0.5 μm to 20 μm, for example, 1 μm to 20 μm, for example, 1 μm to 15 μm, for example, 1 μm to 10 μm, for example, 1 μm to 5 μm, or, for example, 2 μm to 8 μm. The size of the particles is, according to one embodiment, 0.1 μm or greater, for example, 0.1 μm to 20 μm, for example, 0.1 μm to 10 μm or, for example, 10 μm to 20 μm, for example, greater than 10 μm to 20 μm, for example, 11 μm to 20 μm.

In some embodiments, the feature size can be determined by the distribution of particles and may not be impacted by, for example, heating conditions such as heating temperature and time. Heating temperature and time can affect the depth of particle sinking and in turn the spacing between the particles. Higher temperatures and/or longer heating time may cause the particles to sink deeper into the substrate, for example. The surface height of the features may be controlled and optimized, for example, by adjusting the heating conditions. The process offers the possibility of being run in a continuation fashion prior to cutting the sheet into individual pieces and would also work with individual pieces. The features, in some embodiments, are densely packed and only on one surface.

Silica microspheres are available commercially in narrow size distributions with average sizes from 150 nm to 5 μm from Bangs Laboratories (Fishers, IN). The basic concept is to press a monolayer of these microspheres (or other high temperature particles) into a softened glass substrate with control over the particle depth. The resulting textured substrate has a densely packed structure and a controlled depth on a single side of the substrate. A monolayer of high temperature particles is formed on the substrate. In this example, 2.5 μm silica microspheres are used. Initial experiments have also been completed with 0.5 μm and 1.0 μm silica microspheres.

The monolayer can be formed by many methods, for example, the monolayer formation may be done using a self-assembly process, by soot deposition, or using an adhesive formed monolayer. A self-assembly method can be, for example, functionalizing particles with a silane, spreading the functionalized particles on water to form a monolayer, and putting the substrate through the monolayer to deposit the particles onto the substrate; or by other self-assembly methods known in the art. A soot deposition method can be, for example, passing reactants through, for example, a burner to produce soot particles and depositing the soot particles onto the substrate; or by other soot deposition methods known in the art. An adhesive monolayer forming method can be, for example, applying an adhesive to a substrate, applying particles to the adhesive coated substrate, and removing the excess particles to form a monolayer of particles on the substrate; or by other adhesive monolayer forming methods known in the art. The process is not specific to a type of substrate glass. Soda lime substrates are described here. The substrate is then heated in a furnace above its softening point with a weight on top of the sample and subsequently cooled. For demonstration purposes, the substrate was placed into a furnace having shelf paper (Bullseye ThinFire Shelf Paper, Bullseye Glass Co., Portland, Oreg.) on an alumina shelf to prevent sticking. A thin aluminum nitride or alumina ceramic plate was placed on the particle side of the substrate with additional alumina plates placed on top as weights. The entire assembly was temperature cycled with a 10° C./min ramp rate up to between 680° C. and 720° C. and held for 60 minutes prior to cooling. The shelf paper creates a matte finish on the back side of the glass which may or may not be desirable in the photovoltaic application. Note that this is also a lab scale demonstration format and the techniques described below may be better suited to large scale manufacturing.

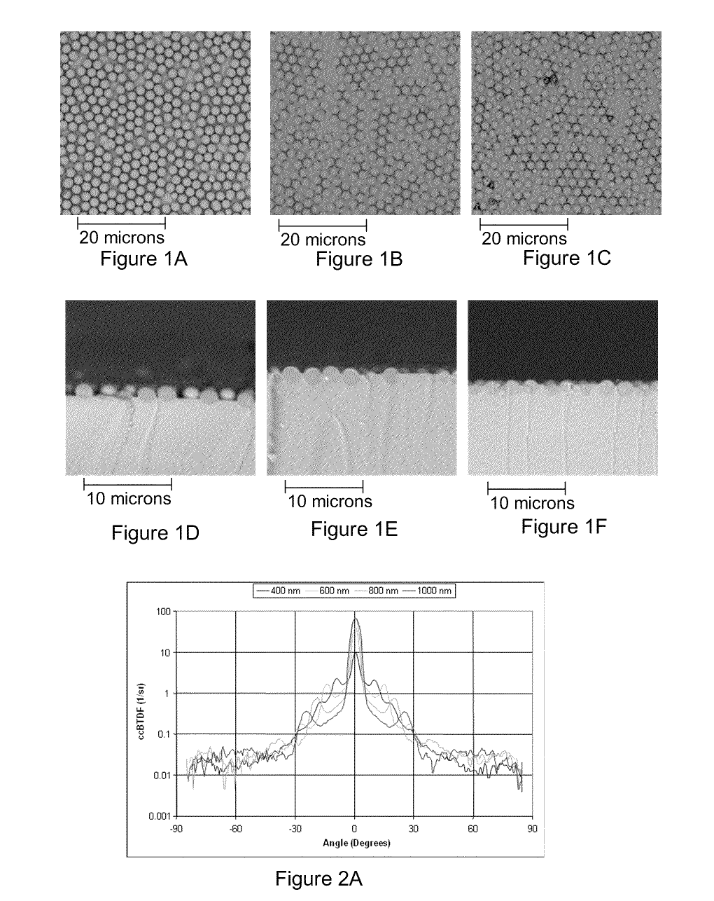

Particle depth was controlled by the peak temperature although it could also be controlled by the amount of weight. FIGS. 1A, 1B, and 1C are top down scanning electron microscope (SEM) images of light scattering inorganic substrates made according to one embodiment. The light scattering inorganic substrates shown in FIGS. 1A, 1B, and 1C were made using 2.5 μm silica microspheres on 2.5×2.5 inch glass and a weight of 650g with peak temperatures of 680° C., 700° C., and 720° C., respectively. FIGS. 1D, 1E, and 1F are cross sectional SEM images of the light scattering inorganic substrates shown in FIGS. 1A, 1B, and 1C, respectively. As the temperature increases, the particles sunk further into the surface of the substrate.

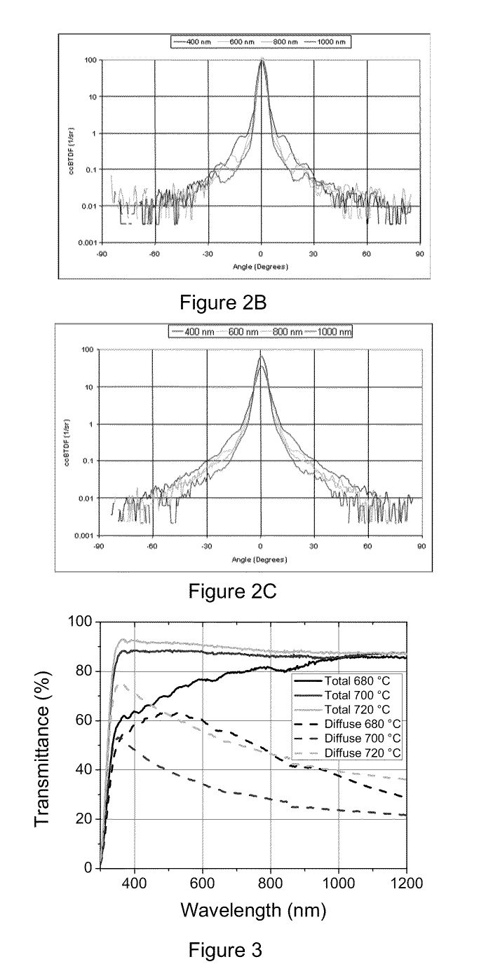

These samples also have very different optical properties as measured by scattering and transmittance. 1-D line scans of ccBTDF (cosine-corrected bidirectional transmittance distribution function) measurements are shown in FIGS. 2A, 2B, and 2C which correspond to the light scattering inorganic substrates shown FIGS. 1A, 1B, and 1C, respectively. Diffraction rings are visible and are from the multiple polycrystalline domains which are misoriented relative to one another producing a circularly symmetric diffraction pattern. The total and diffuse transmittance for the three types of samples is plotted in FIG. 3. The decrease in total transmittance at short wavelengths corresponds with an increase in reflectance at those wavelengths as total internal reflection occurs within the sphere where it protrudes above the surface of the substrate.

While the method described above is suitable for a laboratory demonstration, there may be more preferred approaches that are better suited for large scale manufacturing. There are several possibilities and include Deposit monolayer by self-assembly or transfer adhesive on cold substrate and then reheat and press (as described above), Deposit monolayer on a carrier (belt, drum, substrate, etc.) by self-assembly or adhesive and transfer/press onto substrate at high temperature, spray or sprinkle excess particles on substrate at high temperature followed by pressing and removal of particles that do not form part of the monolayer by brushing, shaking, rinsing, etc. Depending on how this is done, there may be more than a monolayer of particles remaining on the surface.

In one embodiment, the method further comprises removing at least a portion of the particles after heating or after pressing. It is currently not known whether bumps or depressions are the preferred form of features on a glass substrate prior to TCO deposition in thin-film PV solar cells. The processes described above create bumps on the surface which may be transformed to a different surface morphology following TCO deposition depending on the thickness of the TCO and the height of the bumps. If depressions are preferred instead on the glass substrate, it is possible to use a simple chemical etch to pop off, for example, the silica microspheres by differential etching of the substrate glass relative to the silica or by differential etching of the particles, if they are made by a suitable composition. It is also possible to create depressions by pressing coated high temperature microspheres onto a softened glass surface where the coating prevents the microspheres from sticking to the glass.

In one embodiment, after the removing step, the surface has voids, wherein the height of the void is ¾ the maximum dimension of the original particle or less. This is possible, for example, when at least a portion of the particles are irregularly shaped. In one embodiment, after the removing step, the surface has voids in the shape of a truncated sphere, wherein the height of the truncated sphere is ¾ the diameter of the original particle or less, for example, ⅔ or less, for example, ½ or less. The voids can be in the shape of a partial sphere, for example, a truncated sphere such as a hemisphere. One embodiment is an article such as a light scattering substrate comprising a surface having voids created by removing particles from an inorganic substrate. Another embodiment is an article comprising an inorganic substrate having two opposing surfaces; and voids on at least one of the opposing surfaces, the surface has voids, wherein the height of the void is ¾ the maximum dimension of the original particle or less. The article such as a light scattering substrate can be made according to the methods described herein. Another embodiment is a photovoltaic device comprising the article such as a light scattering substrate.

Another embodiment is an article, as shown in FIG. 5, comprising an inorganic substrate 10 having two opposing surfaces (one surface 14 is shown); and voids 24 on at least one of the opposing surfaces (in this embodiment, surface 14), the surface has voids, wherein the height of the voids (or depth of the voids into the substrate) is 0.1 to 20 microns, for example, 0.75 to 15 microns. In one embodiment, the valley to valley (minima to minima), as shown by arrow 26, is less than 40 microns. In some embodiments, the surface has voids in the shape of a truncated sphere, wherein the height of the truncated sphere is ¾ the diameter of the original particle or less, for example, ⅔ or less, for example, ½ or less. The voids can be in the shape of a partial sphere, for example, a truncated sphere such as a hemisphere. The article such as a light scattering substrate can be made according to the methods described herein. Another embodiment is a photovoltaic device comprising the article such as a light scattering substrate.

By controlling the size of the particles, it is possible to fabricate textured glass substrates with small lateral feature sizes which overcomes the limitation of other techniques. By using depth as a parameter, it is also possible to provide a range of feature heights for a given lateral feature size although it is obviously limited by the size of the microspheres. The use of densely packed microspheres also overcomes the limited surface coverage of the approach in which microspheres are distributed in a sol-gel solution.

The inorganic substrate, in one embodiment, comprises a material selected from a glass, a ceramic, a glass ceramic, sapphire, silicon carbide, a semiconductor, and combinations thereof. The glass can be, for example, silica, borosilicate, soda-lime, aluminaborosilicate, or combinations thereof. The inorganic substrate can be in the form of a sheet. The sheet can have substantially parallel opposing surfaces. In some embodiments, the inorganic substrate has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. In one embodiment, the inorganic substrate is in the form of a sheet and has a thickness in the describe range.

In one embodiment, the inorganic particles comprise spheres, microspheres, bodies, symmetrical particles, nonsymmetrical particles, or combinations thereof.

In one embodiment, the inorganic particles can be of any shape or geometric shape, for example, polygonal. The inorganic particles, in one embodiment, comprise a material selected from a glass, a ceramic, a glass ceramic, sapphire, silicon carbide, a semiconductor, silica, alumina, zirconia, glass frit, a metal oxide, a mixed metal oxide, zinc oxide, borosilicate, and combinations thereof.

Generally, any size structures that are generally used by those of skill in the art can be utilized herein. In one embodiment, the structures, for example, particles have average diameters of 20 micrometers (μm) or less, for example, in the range of from 100 nanometers (nm) to 20 μm, for example, in the range of from 100 nanometers (nm) to 10 μm, for example, fpm to 10 μm can be coated using methods disclosed herein.

In one embodiment, the structures have a distribution of sizes, such as diameter. The diameter dispersion of structures is the range of diameters of the structures. Structures can have monodisperse diameters, polydisperse diameters, or a combination thereof. Structures that have a monodisperse diameter have substantially the same diameter. Structures that have polydisperse diameters have a range of diameters distributed in a continuous manner about an average diameter. Generally, an average size of polydisperse structures is reported as the particle size. Such structures will have diameters that fall within a range of values. Using different sized particles to make the light scattering inorganic substrates may lead to enhanced light scattering properties at different wavelengths.

One embodiment is a photovoltaic device comprising the light scattering inorganic substrate made according to the methods disclosed herein. The photovoltaic device, according to one embodiment, further comprises a conductive material adjacent to the substrate, and an active photovoltaic medium adjacent to the conductive material. Another embodiment is a photovoltaic device comprising the articles described herein. The photovoltaic device, according to one embodiment, further comprises a conductive material adjacent to the particles disposed on the substrate. In another embodiment, an active photovoltaic medium is adjacent to the conductive material.

The active photovoltaic medium, according to one embodiment, is in physical contact with the conductive material. The conductive material, according to one embodiment is a transparent conductive film, for example, a transparent conductive oxide (TOO). The transparent conductive film can comprise a textured surface.

The photovoltaic device, in one embodiment, further comprises a counter electrode in physical contact with the active photovoltaic medium and located on an opposite surface of the active photovoltaic medium as the conductive material.

What is claimed is:

1. A method for making a light scattering inorganic substrate, the method comprising:
providing an inorganic substrate comprising at least one surface;
forming a monolayer of inorganic particles on the at least one surface to form a coated substrate; and
heating the coated substrate above the softening point of the inorganic substrate to form the light scattering inorganic substrate.

2. The method according to claim 1 further comprising:
pressing the inorganic particles into the at least one surface after the heating to form the light scattering inorganic substrate.

3. The method according to claim 1, wherein forming the monolayer comprises using a self-assembly process, a soot deposition process, or an adhesive process.

4. The method according to claim 1, wherein the inorganic substrate comprises a material selected from a glass, a ceramic, a glass ceramic, sapphire, silicon carbide, a semiconductor, and combinations thereof.

5. The method according to claim 1, wherein the inorganic particles comprise spheres, microspheres, bodies, symmetrical particles, nonsymmetrical particles, or combinations thereof.

6. The method according to claim 1, wherein the particles comprise a material selected from a glass, a ceramic, a glass ceramic, sapphire, silicon carbide, a semiconductor, silica, alumina, zirconia, glass frit, a metal oxide, a mixed metal oxide, zinc oxide, borosilicate, and combinations thereof.

7. The method according to claim 1, wherein the particles have an average diameter in the range of from 0.1 microns to 20 microns.

8. The method according to claim 1, further comprising removing at least a portion of the particles after heating.

9. The method according to claim 8, wherein after the removing, the surface has voids, wherein the height of the voids is ¾ the maximum dimension of the original particle or less.

10. A photovoltaic device comprising the light scattering inorganic substrate made according to the method of claim 1.

11. The device according to claim 10, further comprising
a conductive material adjacent to the substrate; and
an active photovoltaic medium adjacent to the conductive material.

12. The device according to claim 10, wherein the conductive material is a transparent conductive film.

13. The device according to claim 12, wherein the transparent conductive film comprises a textured surface.

14. The device according to claim 12, wherein the active photovoltaic medium is in physical contact with the transparent conductive film.

15. The device according to claim 11, further comprising a counter electrode in physical contact with the active photovoltaic medium and located on an opposite surface of the active photovoltaic medium as the conductive material.

16. An article comprising:
an inorganic substrate having two opposing surfaces; and
inorganic particles disposed on at least one of the opposing surfaces, wherein a majority of the particles have a portion of their volume above the surface they are disposed on and wherein the portion is less than ¾ of the volume of the particle.

17. The article according to claim 16, wherein the inorganic particles are disposed in a monolayer.

18. The article according to claim 16, wherein the portion is less than ½ of the volume of the particle.

19. The article according to claim 16, wherein the portion is less than ⅓ of the volume of the particle.

20. The article according to claim 16, wherein the majority of the particles have average diameters in the range of from 0.1 to 20 microns, and wherein the majority of the particles have a center-to-center spacing less than twice the particle diameter.

21. A photovoltaic device comprising the article according to claim 16.

22. An article comprising:
an inorganic substrate having two opposing surfaces; and
inorganic particles disposed on at least one of the opposing surfaces, wherein the majority of the particles have average diameters in the range of from 0.1 to 20 microns, and wherein the majority of the particles have a center-to-center spacing less than twice the particle diameter.

23. The article according to claim 22, wherein the inorganic particles are disposed in a monolayer.

24. A photovoltaic device comprising the article according to claim 22.

25. An article comprising an inorganic substrate having two opposing surfaces; and voids on at least one of the opposing surfaces, the surface has voids, wherein the height of the voids are 0.1 to 20 microns.
